(19) United States
(12) Patent Application Publication
(10) Pub. No.: US 2007/0026655 A1
(43) Pub. Date: Feb. 1, 2007

(54) Method of manufacturing a semiconductor device

(75) Inventors: Chul-Sung Kim, Seongnam-si (KR); Yu-Gyun Shin, Seongnam-si (KR); Bon-Young Koo, Suwon-si (KR); Ji-Hyun Kim, Suwon-si (KR); Young-Jin Noh, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/489,985

(22) Filed: Jul. 20, 2006

(30) Foreign Application Priority Data
Jul. 27, 2005 (KR) 10-2005-0068131

(51) Int. Cl. H01L 21/473

(52) U.S. Cl. 438/594; 438/770; 438/771

(57) ABSTRACT

In a method of manufacturing a semiconductor device for use in such applications as a flash memory device, a field insulating pattern defines an opening that exposes an active region of a semiconductor substrate. The field insulating pattern includes a first portion protruding from the substrate and a second portion buried in the substrate. An oxide layer is formed on the active region by an oxidation process using a reactive plasma including an oxygen radical and a conductive layer is then formed on the oxide layer to sufficiently fill up the opening. The oxide layer is formed by an oxidation reaction of a surface portion of the active region with the oxygen radical having a relatively low activation energy, resulting in an improved thickness uniformity of the oxide layer. As a result, various performance characteristics of the semiconductor device when used in flash memory and similar applications are improved.

### CROSS REFERENCE TO RELATED APPLICATION

This application claims the benefit under 35 USC § 119 of Korean Patent Application No. 2005-68131 filed on Jul. 27, 2005, the disclosure of which is hereby incorporated herein by reference in its entirety as if set forth fully herein.

### BACKGROUND OF THE INVENTION

1. Field of the Invention

The present invention relates to a method of manufacturing a semiconductor device. More particularly, the present invention relates to a method of manufacturing a semiconductor device including a floating gate electrode of a self-aligned polysilicon (SAP).

2. Description of the Related Art

A semiconductor device, in general, may be classified as either a volatile semiconductor memory device or a non-volatile semiconductor memory device. Volatile semiconductor memory devices, such as dynamic random access memory (DRAM) devices and/or static random access memory (SRAM) devices, have a relatively high response speed. However, the volatile semiconductor memory devices lose data stored therein when power is shut off. Although non-volatile semiconductor memory devices, such as electrically erasable programmable read only memory (EEPROM) devices and/or flash memory devices, have a relatively slow response speed, non-volatile semiconductor memory devices can maintain data stored therein when power is shut off. In EEPROM devices, for example, data is electrically stored (i.e., programmed) or erased through a Fowler-Nordheim (F-N) tunneling mechanism and/or a channel hot electron injection mechanism.

A conventional flash memory device has a gate structure formed on an active region of a semiconductor substrate such as a silicon wafer, which includes a tunnel oxide layer pattern, a floating gate electrode, a dielectric layer pattern and a control gate electrode.

The gate structure for such a flash memory device may be formed by patterning a tunnel oxide layer, a first conductive layer for the floating gate electrode, a dielectric layer and a second conductive layer for the control gate electrode sequentially on the semiconductor substrate. However, as a packing density of the semiconductor device has become more highly integrated, it has become necessary to reduce the alignment margin between a gate mask for forming the gate structure and the active region defined by an isolation layer. To improve the reduction of alignment margin, a self-alignment method has been employed.

For example, in accordance with a conventional method using a self-aligned polysilicon technique, a mask pattern having a first opening is primarily formed on a semiconductor substrate so as to partially expose a surface of the semiconductor substrate. A trench is formed in the exposed surface portion of the semiconductor substrate using the mask pattern. A field insulating pattern is then formed in the first opening and the trench. A second opening that exposes an active region defined by the field insulating pattern is next formed by removing the mask pattern. A tunnel oxide layer is then formed on the active region, and a self-aligned floating gate electrode is then formed on the tunnel oxide layer by filling up the second opening with impurity-doped polysilicon.

In the above-described method using the self-aligned polysilicon technique, the tunnel oxide layer is commonly formed by a thermal oxidation process. Here, an oxidation reaction is suppressed because of stresses applied to edge portions of the active region while forming the trench, and thus the thicknesses of edge portions of the tunnel oxide layer become thinner than the thickness of a central portion of the tunnel oxide layer.

In such cases where the tunnel oxide layer lacks thickness uniformity, leakage current through the thinner edge portions of the tunnel oxide layer may be increased, and electron tunneling may occur at a voltage lower than a desired predetermined voltage. As a result, endurance of the tunnel oxide layer and the overall data retention performance of the floating gate electrode are impaired, and thus the operating reliability of a completed flash memory device incorporating such a structure is unnecessarily reduced.

### SUMMARY OF THE INVENTION

Example embodiments of the present invention provide methods of manufacturing a semiconductor device capable of forming an oxide layer having a substantially uniform thickness on an active region defined by a field insulating pattern.

In one aspect of the present invention, a field insulating pattern having an opening is formed to expose an active region of a substrate. The field insulating pattern includes a first portion protruding from the substrate and a second portion buried in the substrate. A reactive plasma including an oxygen radical is supplied onto the substrate to oxidize a surface portion of the active region so that the surface portion of the active region is formed into an oxide layer. A conductive layer is then formed on the oxide layer and the field insulating pattern so that the opening is filled up.

In some embodiments of the present invention, the oxide layer may be formed at a temperature of about 800 to about 1100° C. so that both a radical oxidation treatment using the oxygen radical and a thermal oxidation treatment using thermal energy may be simultaneously performed. Thus, thickness uniformity and electrical characteristics of the oxide layer may thereby be improved.

In some embodiments of the present invention, after forming the oxide layer, a nitridation treatment and/or a heat treatment may be performed on the oxide layer to at least partly cure defects of the oxide layer, thereby improving electrical characteristics of the oxide layer.

In some embodiments of the present invention, the oxide layer may be formed by a primary oxidation and a secondary oxidation. The primary oxidation may be performed at a temperature of about 350 to about 650° C. using the oxygen radical, and the secondary oxidation may be performed at a temperature of about 800 to about 1100° C. using a reactive gas including oxygen. Alternatively, the secondary oxidation may be performed at a temperature of about 800 to about 1100° C. using a reactive plasma as described above so that a radical oxidation and a thermal oxidation are substantially simultaneously accomplished by the oxygen radical and thermal energy.

In accordance with example embodiments of the present invention, the oxide layer may serve as a tunnel oxide layer of a flash memory device and be formed by an oxygen radical having a relatively low activation energy, thereby improving the thickness uniformity of the oxide layer. Further, the electrical characteristics of the oxide layer may be improved by adjustment of the oxidation reaction temperature, a subsequent nitridation treatment, a subsequent heat treatment, and the like.

### BRIEF DESCRIPTION OF THE DRAWINGS

Example embodiments of the present invention will become readily apparent through the following detailed description when considered in conjunction with the accompanying drawings wherein:

FIG. 1 is a schematic cross-sectional view illustrating a pad oxide layer and a mask layer formed on a semiconductor substrate;

FIG. 2 is a schematic cross-sectional view illustrating a mask pattern formed from the mask layer as shown in FIG. 1;

FIG. 3 is a schematic cross-sectional view illustrating a trench formed in the semiconductor substrate using the mask pattern as shown in FIG. 2;

FIG. 4 is a schematic cross-sectional view illustrating a field insulating pattern formed in the trench as shown in FIG. 3;

FIG. 5 is a schematic cross-sectional view illustrating how a second opening in the structure shown in FIG. 4 exposes an active region of the semiconductor device;

FIG. 6 is a schematic cross-sectional view illustrating a tunnel oxide layer formed on the exposed portion of the active region as shown in FIG. 5;

FIG. 7 is a schematic cross-sectional view illustrating a first conductive layer formed on the tunnel oxide layer as shown in FIG. 6;

FIG. 8 is a schematic cross-sectional view illustrating how the first conductive layer shown in FIG. 7 becomes a self-aligned conductive pattern formed on the tunnel oxide layer of the semiconductor device;

FIG. 9 is a schematic cross-sectional view illustrating how a semiconductor device including a floating gate electrode is obtained from the device having the conductive pattern as shown in FIG. 8;

FIG. 10 is a schematic cross-sectional view illustrating a tunnel oxide layer formed on an active region of a semiconductor substrate; and

FIG. 11 is a schematic cross-sectional view illustrating how a semiconductor device having a gate structure is formed on the tunnel oxide layer as shown in FIG. 10.

### DESCRIPTION OF THE EMBODIMENTS

The invention now will be described more fully hereinafter with reference to the accompanying drawings, in which embodiments of the invention are shown. It will be understood, however, that this invention may be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will also be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will further be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The example term “lower,” can therefore, encompass both an orientation of “lower” and “upper,” depending of the particular orientation of the figure. Similarly, if the device in one of the figures is turned over, elements described as “below” or “beneath” other elements would then be oriented “above” the other elements. The example terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and should not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes and relative sizes, thicknesses, and so forth, are not intended to illustrate the precise shape/size/thickness of a region and are not intended to limit the scope of the present invention.

Hereinafter, embodiments of the present invention will be explained in detail with reference to the accompanying drawings.

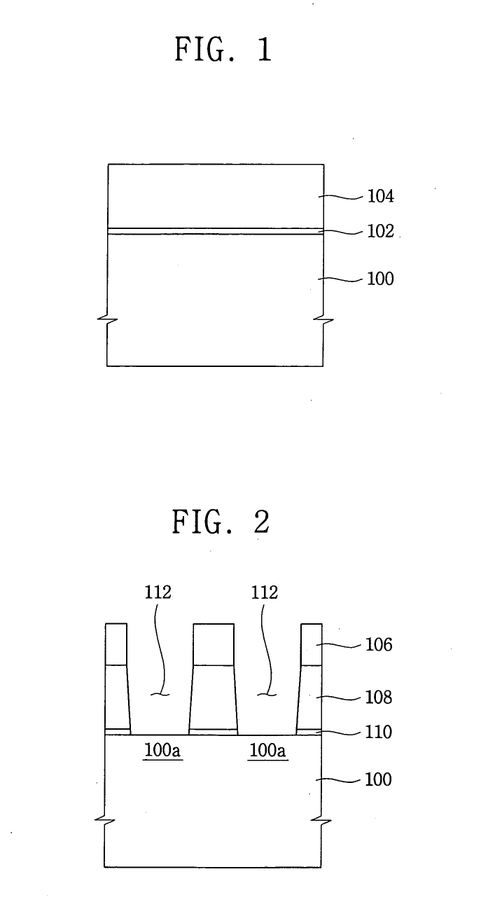

FIGS. 1 to 9 are schematic cross-sectional views illustrating a method of manufacturing a semiconductor device in accordance with an example embodiment of the present invention.

FIG. 1 is a schematic cross-sectional view illustrating a pad oxide layer and a mask layer formed on a semiconductor substrate, and FIG. 2 is a schematic cross-sectional view illustrating a mask pattern formed from the mask layer as shown in FIG. 1.

Referring to FIGS. 1 and 2, a pad oxide layer 102 is formed on a semiconductor substrate 100, such as a silicon wafer, and a mask layer 104 is then formed on the pad oxide layer 102.

The pad oxide layer 102 may be formed to a thickness of about 70 to about 100 Å by, for example, a thermal oxidation process or a chemical vapor deposition (CVD) process. Further, the pad oxide layer 102 may be desirably formed at a temperature of about 750 to about 900° C. in order to also effect a surface treatment of the semiconductor substrate 100.

The mask layer 104 in FIG. 1 may include silicon nitride and be formed to a thickness of about 1500 Å by, for example, a low pressure chemical vapor deposition (LPCVD) process or a plasma enhanced chemical vapor deposition (PECVD) process using SiH₂Cl₂, SiH₄, NH₃, and the like.

As shown in FIG. 2, a photoresist pattern 106 partially exposing a surface of the mask layer 104 is formed on the mask layer 104 for example by a photolithography process. In such a process, the mask layer 104 and the pad oxide layer 102 are sequentially etched away by an etching process using the photoresist pattern 106 as an etching mask, thereby forming a mask pattern 108 and a pad oxide pattern 110 on the semiconductor substrate 100. As seen in FIG. 2, the mask pattern 108 and the pad oxide pattern 110 define first opening(s) 112 exposing isolation region(s) 100a of the semiconductor substrate 100.

For example, the mask layer 104 and the pad oxide layer 102 may be etched away by a dry etching process using a plasma or a reactive ion etching process. The photoresist pattern 106 is removed by ashing and stripping processes after forming the mask pattern 108 and the pad oxide pattern 110.

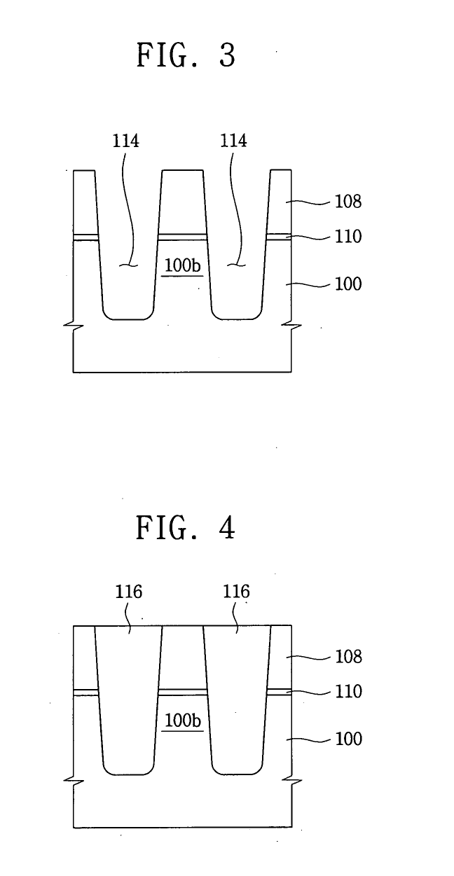

FIG. 3 is a schematic cross-sectional view illustrating a trench formed in the semiconductor substrate 100 using the mask pattern as shown in FIG. 2, and FIG. 4 is a schematic cross-sectional view illustrating a field insulating pattern formed in the trench as shown in FIG. 3.

Referring to FIGS. 3 and 4, an etching process using the mask pattern 108 as an etching mask is performed to etch away the isolation region(s) 100a (FIG. 2) of the semiconductor substrate 100, thereby forming a trench 114 extending in a first direction across the semiconductor substrate 100 so as to define an active region 100b. The trench 114 may be formed to a depth of about 1000 to about 5000 Å from the surface of the semiconductor substrate 100.

Alternatively, a thermal oxidation process on sidewalls of the trench 114 may be additionally performed so as to at least partly cure silicon damages caused by high energy ion impactions during the etching process for forming the trench 114 and also to prevent or at least reduce generation of leakage current through the sidewalls of the trench 114. Trench oxide layers (not shown) may be formed to a thickness of about 50 to about 250 Å on the inner surfaces of the sidewalls of the trench 114 during such a thermal oxidation process.

Further, liner nitride layers (not shown) may be formed to a thickness of about 50 to about 100 Å on the trench oxide layers so as to reduce or prevent diffusion of impurities, such as carbon and hydrogen, from a subsequently formed layer, e.g., a field insulating layer, into the active region 100b defined by the trench 114.

Then, a field insulating layer (not seen in FIG. 3 or FIG. 4 because this represents an intermediate processing step between FIG. 3 and FIG. 4) is formed on the semiconductor substrate 100 in which the trench 114 is formed so as to sufficiently fill up the trench 114 and first opening(s) 112 (FIG. 2). The field insulating layer may include silicon oxide, such as undoped silicate glass (USG), tetra ethyl ortho silicate (TEOS) oxide, high density plasma (HDP) CVD oxide, and the like. The field insulating layer may be formed for example by a HDP CVD process using SiH₄, O₂ and Ar as plasma source gases.

A planarization process, such as a chemical mechanical polishing process, is then performed to remove an upper portion of the field insulating layer until the mask pattern 108 is exposed, thereby forming a field insulating pattern 116 in the trench 114 and the first opening(s) 112 as seen in FIG. 4. The field insulating pattern 116 serves as an isolation layer and defines the active region 100b of the semiconductor substrate 100.

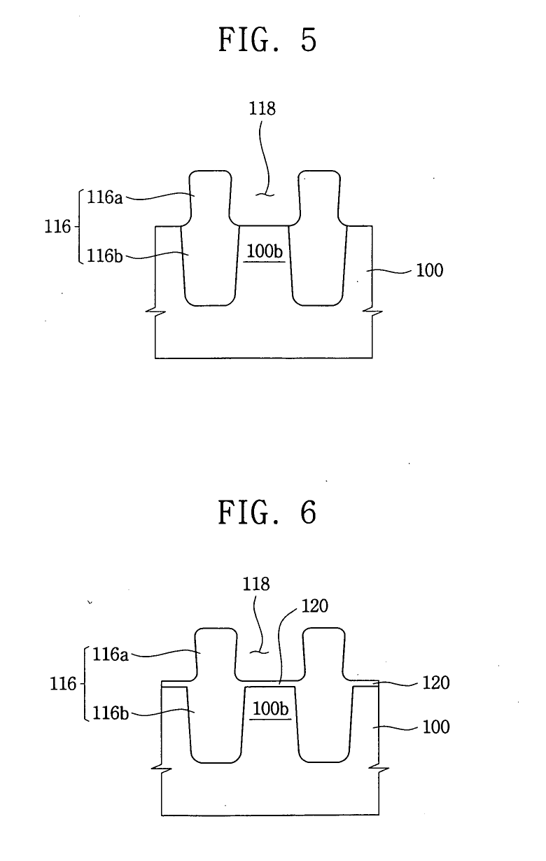

FIG. 5 is a schematic cross-sectional view illustrating further processing of the semiconductor device seen in FIG. 4 so as to form a second opening 118 that exposes an active region 100b. FIG. 6 is a schematic cross-sectional view illustrating a tunnel oxide layer formed on the exposed portion of active region 100b as shown in FIG. 5.

Referring to FIGS. 5 and 6, the mask pattern 108 and the pad oxide layer pattern 110 as seen in FIG. 4 are removed to form a second opening 118 (FIG. 5) exposing an active region 100b of the semiconductor substrate 100. In one embodiment, the mask pattern 108 may be removed by an etching solution including phosphoric acid, and the pad oxide layer pattern 110 may be removed by a diluted hydrofluoric acid solution. As shown in a somewhat exaggerated form in the figures, portions (especially corner portions) of the field insulating pattern 116 may be partially removed by the treatment steps in which the mask pattern 108 and the pad oxide layer pattern 110 are removed. Thus, after treatment to remove the mask pattern 108 and the pad oxide layer pattern 110, the remaining portion of the field insulating pattern 116 includes a first portion 116a that protrudes from the surface of the semiconductor substrate 100, and a second portion 116b buried in the semiconductor substrate 100. The first portion 116a has a first width and the second portion 116b has a second width that is typically wider than the first width of the first portion 116a.

As described above, because the field insulating pattern 116 is partially removed by the previously described processing steps, a width of the second opening 118 typically becomes wider than the corresponding width of the active region 100b, and thus a contact area between a floating gate electrode and a dielectric layer that will be subsequently formed on this semiconductor structure may be increased. As a result, a coupling ratio of a gate structure may be improved.

As seen in FIG. 6, a tunnel oxide layer 120 may now be formed on the active region 100b exposed through the second opening 118. The tunnel oxide layer 120 may be formed, for example, by supplying a reactive plasma including an oxygen radical onto the semiconductor substrate 100. In this step, the tunnel oxide layer 120 is formed by an oxidation reaction of a surface portion of the active region 100b with the oxygen radical.

In this invention embodiment, after the semiconductor substrate 100 is positioned in a reaction chamber, the reactive plasma is supplied onto the semiconductor substrate 100. The reactive plasma may be formed for example by exciting a reactive gas including oxygen. For example, the reactive plasma may be directly formed in the reaction chamber and provided by a remote plasma generator connected to the reaction chamber. In a particular embodiment, the reactive plasma may be formed by supplying the reactive gas into the reaction chamber and applying radio frequency energy to the reactive gas. Alternatively, the reactive plasma may be formed by applying microwave energy to the reactive gas passing through the remote plasma generator.

Further, the reactive gas may also include an inert gas serving as a plasma ignition gas. Particularly, the reactive gas may further include an inert gas, such as an argon gas, a nitrogen gas, a helium gas, or the like, for igniting and maintaining the reactive plasma.

The oxygen radical has a relatively low activation energy, and thus the oxidation reaction may be performed at a first temperature of about 350 to about 650° C., e.g., about 400° C. Further, even though stresses are applied to edge portions of the active region 100b by the etching process used for forming the trench 114 (FIG. 3), the oxidation reaction according to this embodiment of the invention may be uniformly accomplished on the entire surface portion of the active region 100b, and, as a result, thickness uniformity of the tunnel oxide layer 120 may be improved.

Alternatively, in another embodiment, the oxidation reaction may be performed at a second temperature of about 800 to about 1100° C. so that a radical oxidation and a thermal oxidation may be simultaneously accomplished by the oxygen radical and the thermal energy, respectively. When the oxidation reaction is performed at such a second temperature using the reactive plasma in accordance with this invention embodiment, the tunnel oxide layer 120 may be formed to a uniform thickness by the radical oxidation, and defects of the tunnel oxide layer 120 thus formed may be at least partly cured by the thermal oxidation.

Further, when the oxidation reaction is performed at the second temperature, an oxygen gas or a gas mixture of oxygen and hydrogen may be used as the reactive gas. When oxygen gas is used as the reactive gas, the radical oxidation using the oxygen radical and a dry thermal oxidation may be substantially simultaneously accomplished. On the other hand, when the gas mixture is used as the reactive gas, the radical oxidation using the oxygen radical and a wet thermal oxidation using water vapor may be substantially simultaneously accomplished.

When the tunnel oxide layer 120 is formed at the first temperature by the radical oxidation, defects in the tunnel oxide layer 120 may be cured at least partially by subsequently heat treating the tunnel oxide layer 120 at a temperature of about 800 to about 1100° C., preferably under an atmosphere including nitric oxide (NO), nitrous oxide (N₂O), ammonia (NH₃), nitrogen (N₂) or a mixture thereof, after forming the tunnel oxide layer 120. Alternatively, the heat treatment may be performed under an atmosphere including an inert gas such as an argon (Ar) gas or a helium (He) gas.

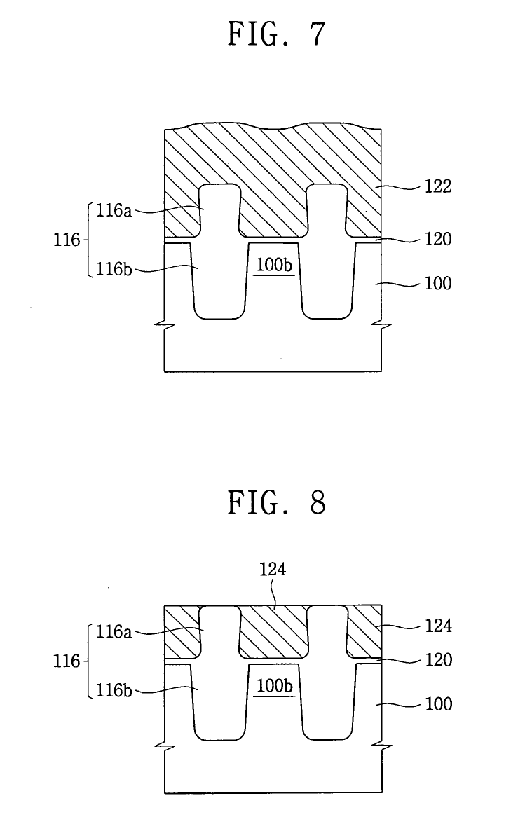

FIG. 7 is a schematic cross-sectional view illustrating a first conductive layer 122 formed on the tunnel oxide layer 120 as shown in FIG. 6. FIG. 8 is a schematic cross-sectional view illustrating how the first conductive layer 122 seen in FIG. 7 becomes a self-aligned conductive pattern formed on the tunnel oxide layer.

Referring to FIGS. 7 and 8, a first conductive layer 122 is formed on the tunnel oxide layer 120 and the field insulating pattern 116 (as seen in FIG. 6) so as to sufficiently fill up the second opening 118. The first conductive layer 122 may include impurity-doped polysilicon and may be formed by an LPCVD process using SiH₄ gas.

In one embodiment, the first conductive layer 122 may be formed at a temperature of about 580 to about 620° C. using a SiH₄ gas and a PH₃ gas. In an alternative embodiment, the first conductive layer 122 may be constituted by forming a polysilicon layer using a SiH₄ gas and subsequently performing impurity diffusion or ion implantation on the polysilicon layer.

After forming the first conductive layer 122, a planarization process is performed to obtain a self-aligned conductive pattern 124 with respect to the active region 100b until the field insulating pattern 116 is exposed as shown in FIG. 8. Particularly, the first conductive layer 122 may be planarized by a chemical mechanical polishing (CMP) process or an etching back process.

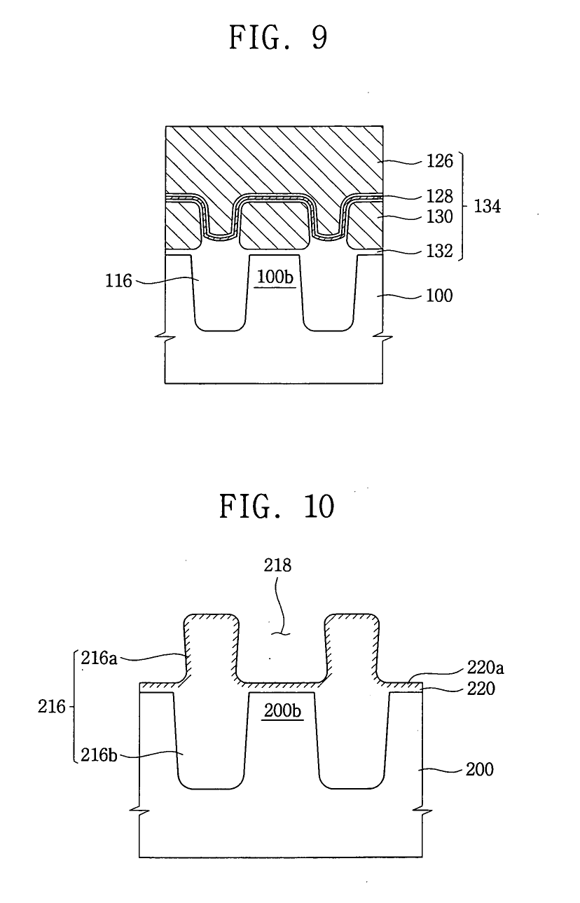

FIG. 9 is a schematic cross-sectional view illustrating a semiconductor device including a floating gate electrode 130 obtained from the conductive pattern 124 as shown in FIG. 8.

Referring to FIG. 9, an upper portion of the field insulating pattern 116 is removed to expose upper sidewall portions of the conductive pattern 124. The field insulating pattern 116 may be partially removed, for example, by an isotropic or anisotropic etching process. The etching process may be desirably performed so that the tunnel insulating layer 120 is not exposed, thereby preventing damage to the tunnel oxide layer 120 due to etching solution or etching gas. Further, edge portions of the conductive pattern 124 may become rounded while removing the upper portion of the field insulating pattern 116.

Then, a dielectric layer (not shown because this is an intermediate processing step) is formed on the conductive pattern 124 and the field insulating pattern 116. The dielectric layer may include composite material such as oxide/nitride/oxide (ONO), a high-k material, or the like. A composite dielectric layer including the composite material may be formed by an LPCVD process, and a high-k material layer may include Al₂O₃, Y₂O₃, HfO₂, ZrO₂, Nb₂O₅, BaTiO₃, SrTiO₃, and the like, and such layer may be formed by an atomic layer deposition (ALD) or metal organic chemical vapor deposition (MOCVD) process.

A second conductive layer (not shown because this is an intermediate processing step) is formed on the dielectric layer. The second conductive layer may include impurity doped polysilicon, metal silicide, and the like. The metal suicide may include tungsten silicide (WSiₓ), titanium silicide (TiSiₓ), cobalt silicide (CoSiₓ), tantalum silicide (TaSiₓ), and the like.

The second conductive layer is then patterned so as to form a control gate electrode 126 (FIG. 9) extending in a second direction that is different from the earlier-mentioned first direction (as mentioned in connection with the description of FIGS. 3 and 4). In a preferred embodiment, said second direction may be substantially orthogonal to said first direction. Further, the dielectric layer, the conductive pattern 124 and the tunnel oxide layer 120 are sequentially patterned so as to constitute a gate structure 134 of the semiconductor device, which is useful in applications such as in a flash memory device. Gate structure 134 includes the control gate electrode 126 (comprising the material of said second conductive layer), a dielectric layer pattern 128 (comprising the dielectric material), a floating gate electrode 130 (comprising the material of said first conductive layer) and a tunnel oxide layer pattern 132 (comprising the tunnel oxide material).

Though not shown in the figures, source/drain regions are formed at surface portions of the active region 100b of the semiconductor substrate 100 adjacent to the gate structure 134 by using an impurity-doping process so that an improved flash memory device according to this invention may be constituted.

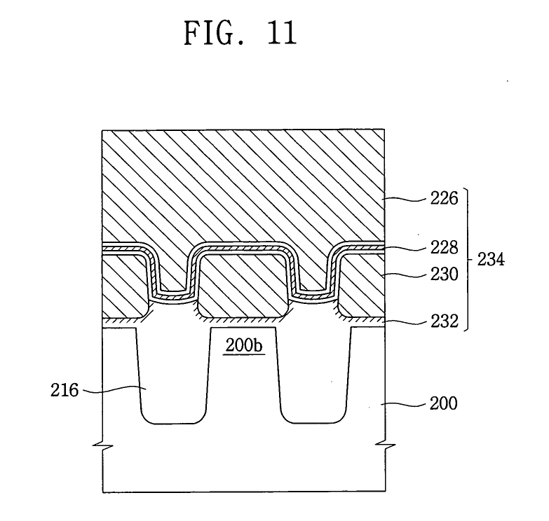

FIGS. 10 and 11 are schematic cross-sectional views illustrating a method of manufacturing a semiconductor device in accordance with another example embodiment of the present invention.

FIG. 10 is a schematic cross-sectional view illustrating a tunnel oxide layer formed along an active region of a semiconductor substrate, and FIG. 11 is a schematic cross-sectional view illustrating a gate structure formed on the tunnel oxide layer as shown in FIG. 10.

Referring to FIGS. 10 and 11, a field insulating pattern 216 having an opening 218 is formed by a series of steps comparable to that described above with reference to FIGS. 1 to 5 so as to expose an active region 200b of a semiconductor substrate 200. The field insulating pattern 216 includes a first portion 216a that protrudes from the surface of semiconductor substrate 200, and a second portion 216b buried in the semiconductor substrate 200. The first portion 216a has a first width and the second portion 216b has a second width that is typically wider than the first width of the first portion 216a. Here, further detailed descriptions of a method of forming the field insulating pattern 216 will be omitted because these are similar to those already described in connection with the field insulating pattern 116 as shown in FIGS. 1 to 5.

As seen in FIG. 10, a tunnel oxide layer 220 is formed on the active region 220b exposed through the opening 218. The tunnel oxide layer 220 may be formed, for example, by supplying a reactive plasma including an oxygen radical onto the semiconductor substrate 200. In this step, an oxidation reaction using the oxygen radical may be performed at a temperature of about 350 to about 650° C.

A surface portion of the tunnel oxide layer 220 is then formed into a silicon oxynitride layer 220a by nitriding the tunnel oxide layer 220. Defects in the tunnel oxide layer 220 may be at least partially removed while nitriding the tunnel oxide layer 220. The silicon oxynitride layer 220a is formed to facilitate electron tunneling and to improve data retention performance.

For example, the nitridation treatment may be performed at a temperature of about 350 to about 650° C. using a nitrogen plasma. Further, a subsequent heat treatment may be performed to at least partly cure damages generated during the plasma nitridation treatment. Such a subsequent heat treatment may be performed at a temperature of about 800 to about 1100° C. and preferably under an atmosphere including nitric oxide (NO), nitrous oxide (N₂O), ammonia (NH₃), nitrogen (N₂), argon (Ar) or a mixture thereof.

Alternatively, the silicon oxynitride layer 220a may be formed by a thermal nitridation treatment using NH₃ gas. Such a thermal nitridation treatment may be performed at a temperature of about 800 to about 1100° C., and thus defects in the tunnel oxide layer 220 may also be at least partly cured during the thermal nitridation treatment.

After forming the tunnel oxide layer 220 and the silicon oxynitride layer 220a, a first conductive layer (not shown because this is an intermediate processing step) is formed to sufficiently fill up the opening 218. A planarization process is then performed to form a conductive pattern (not shown because this is an intermediate processing step). The field insulating pattern 216 is partially removed, and a dielectric layer (not shown) and a second conductive layer (not shown because this is an intermediate processing step) are formed on the conductive pattern and the field insulating pattern. The second conductive layer, the dielectric layer, the conductive pattern and the nitrided tunnel oxide layer 220 are then sequentially patterned to thereby constitute a gate structure 234 (as shown in FIG. 11) of an improved flash memory device according to this invention. The gate structure 234 includes a control gate electrode 226 (comprising the material of said second conductive layer), a dielectric layer pattern 228 (comprising the dielectric material), a floating gate electrode 230 (comprising the material of said first conductive layer) and a nitrided tunnel oxide layer pattern 232. Here, further detailed descriptions of a method of forming the gate structure 234 will be omitted because these are similar to those already described in connection with the gate structure 134 as shown in FIGS. 7 to 9.

In accordance with still another embodiment of present invention, the tunnel oxide layer 120, as shown in FIG. 6, may be formed by a primary oxidation step and a secondary oxidation step on the surface portion of the active region 100b. Particularly, the primary oxidation may be performed at a temperature of about 350 to about 650° C. using a reactive plasma including an oxygen radical. The secondary oxidation may be a thermal oxidation performed at a temperature of about 800 to about 1100° C. using a reactive gas including oxygen.

Alternatively, the secondary oxidation may be performed at a temperature of about 800 to about 1100° C. using the reactive plasma so that a radical oxidation and a thermal oxidation may be substantially simultaneously performed by the oxygen radical and the thermal energy respectively.

The secondary oxidation is performed for densifying the tunnel oxide layer 120 and for at least partially removing or curing defects in the tunnel oxide layer 120.

In accordance with example embodiments of the present invention, a tunnel oxide layer is formed by the oxidation process using an oxygen radical having the relatively low activation energy, and thus the thickness uniformity of the resulting tunnel oxide layer may be improved. Further, the electrical characteristics of a tunnel oxide layer in accordance with this invention may be improved by adjustment of the oxidation reaction temperature, the subsequent nitridation treatment, the subsequent heat treatment, and the like.

Therefore, endurance of the tunnel oxide layer and data retention performance characteristics of a floating gate electrode in accordance with example embodiments of the invention may be improved, and thus the operating reliability of a flash memory device that incorporates a semiconductor apparatus fabricated in accordance with example embodiments of the invention may be improved.

Although example embodiments of the present invention have been described, it is understood that the present invention should not be limited to these example embodiments, and that various changes and modifications can be made by one skilled in the art within the spirit and scope of the present invention as hereinafter claimed.

What is claimed is:

1. A method of manufacturing a semiconductor device comprising:
forming on a semiconductor substrate a field insulating pattern that includes a first portion protruding from the substrate and a second portion buried in the substrate, wherein the field insulating pattern defines an active region of the substrate and has an opening to expose at least a surface portion of the active region of the substrate;
supplying a reactive plasma including an oxygen radical onto the substrate to oxidize the surface portion of the active region so that the surface portion of the active region is formed into an oxide layer; and
forming a conductive layer on the oxide layer and the field insulating pattern such that the opening is filled up.

2. The method of claim 1, wherein the oxide layer is formed at a temperature of about 800 to about 1100° C. so that both a radical oxidation using the oxygen radical and a thermal oxidation using thermal energy are substantially simultaneously performed.

3. The method of claim 1, wherein the oxide layer is formed at a temperature of about 350 to about 650° C. so that a radical oxidation using the oxygen radical is performed.

4. The method of claim 3, further comprising heat treating the oxide layer at a temperature of about 800 to about 1100° C. so as to at least partly cure defects of the oxide layer.

5. The method of claim 4, wherein the heat treatment is performed under at atmosphere including at least one selected from the group consisting of nitric oxide (NO), nitrous oxide (N₂O), ammonia (NH₃), nitrogen (N₂) and argon (Ar).

6. The method of claim 3, further comprising nitriding the oxide layer so as to form a surface portion of the oxide layer into an oxynitride layer.

7. The method of claim 6, wherein nitriding the oxide layer is performed at a temperature of about 350 to about 650° C. using a nitrogen plasma.

8. The method of claim 7, further comprising heat treating the oxide layer and the oxynitride layer at a temperature of about 800 to about 1100° C. so as to at least partly cure defects of the oxide layer and the oxynitride layer.

9. The method of claim 6, wherein nitriding the oxide layer is performed at a temperature of about 800 to about 1100° C. using a nitriding gas including nitrogen.

10. The method of claim 3, further comprising secondarily oxidizing the surface portion of the active region at a temperature of about 800 to about 1100° C. using a reactive gas including oxygen so that a thermal oxidation is performed by thermal energy.

11. The method of claim 1, wherein the oxide layer is formed by a primary oxidation and a secondary oxidation, wherein the primary oxidation is performed at a temperature of about 350 to about 650° C. so that a radical oxidation is accomplished by the oxygen radical and the secondary oxidation is performed at a temperature of about 800 to about 1100° C. so that a radical oxidation and a thermal oxidation are substantially simultaneously accomplished by the oxygen radical and thermal energy.

12. The method of claim 1, wherein the reactive plasma is formed from a reactive gas including oxygen.

13. The method of claim 12, wherein the reactive gas further includes hydrogen.

14. The method of claim 12, wherein the reactive gas further includes an inert gas serving as a plasma ignition gas.

15. The method of claim 1, wherein forming the field insulating pattern includes:
forming a mask pattern on the substrate to expose a field region of the substrate;
etching away the exposed field region to form a trench defining the active region;
forming a field insulating layer on the mask pattern so as to fill up the trench;
planarizing the field insulating layer until the mask pattern is exposed so as to form the field insulating pattern; and
removing the mask pattern so as to form the opening.

16. The method of claim 1, further comprising:
planarizing the conductive layer until the field insulating pattern is exposed so as to form a conductive pattern on the oxide layer;
partially removing the field insulating pattern to partially expose side surfaces of the conductive pattern;
forming a dielectric layer on an upper surface and the exposed side surface portions of the conductive pattern;
forming a second conductive layer on the dielectric layer; and
sequentially patterning the second conductive layer, the dielectric layer, the conductive pattern and the oxide layer so as to constitute a gate structure that includes a control gate electrode, a dielectric layer pattern, a floating gate electrode and a tunnel oxide pattern.
